(19) United States
(12) Patent Application Publication
(10) Pub. No.: US 2007/0048987 A1
(43) Pub. Date: Mar. 1, 2007

(54) Manufacturing method of semiconductor device

(75) Inventor: Tomoya Satonaka, Yokohama-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(73) Assignee: KABUSHIKI KAISHA TOSHIBA

(21) Appl. No.: 11/483,536

(22) Filed: Jul. 11, 2006

(30) Foreign Application Priority Data
Aug. 28, 2005 (JP) P2005-218750

(51) Int. Cl. H01L 21/3205; H01L 21/461

(52) U.S. Cl. 438/585; 438/706; 438/719; 438/722

(57) ABSTRACT

Disclosed is a manufacturing method of a semiconductor device which comprising: preparing a substrate having a gate electrode film formed thereon and a gate insulation film formed between the substrate and the gate electrode film; and etching the gate electrode film formed on the gate insulation film of the substrate using an etching gas which contains a Si-containing gas and O₂.

### CROSS-REFERENCE TO THE RELATED APPLICATIONS

This application is based upon and claims the benefit of priority from the prior Japanese Patent Application No. 2005-218750, filed on Jul. 28, 2005; the entire contents of which are incorporated herein by reference.

### BACKGROUND

1. Field of the Invention

The present invention relates to a manufacturing method of a semiconductor device.

2. Description of the Related Art

Along with miniaturization of semiconductor devices, it is gradually becoming difficult to form a gate electrode of a MOSFET (Metal-Oxide-Semiconductor field effect transistor) by dry etching (refer to, for example, JP-A 10-172959 (KOKAI), JP-A 11-54481(KOKAI)).

Generally, the gate electrode is formed by etching a gate electrode film formed on a gate insulation film, in which it is important in the etching to prevent side etching of the gate electrode film and not to break the gate insulation film by overetching.

At present, this etching is performed through many steps, in which the step of etching a lower portion of the gate electrode film to expose the gate insulation film is performed under the conditions where an etching gas exhibiting a larger etching selectivity of the gate electrode film as compared to the gate insulation film is used and ion energy is suppressed to low level, so as not to break the gate insulation film due to overetching.

However, when the etching is performed under the condition where the ion energy is suppressed to low level, isotopic element increases to easily cause the side etching at the lower portion of the gate electrode film. As a result, the fluctuation in a gate threshold voltage (Vth) increases, causing the characteristics of the transistor to vary.

Above all, when a gate electrode film to form an n-channel MOSFET and a gate electrode film to form a p-channel MOSFET, which are formed on the same semiconductor substrate, are etched at once, the etch rate of the gate electrode film to form the n-channel MOSFET is larger than the etch rate of the gate electrode film to form the p-channel MOSFET due to the difference in impurities introduced into the respective gate electrodes, in which the lower portion of the gate electrode for the n-channel MOSFET is etched excessively to easily cause the side etching.

### SUMMARY

According to an aspect of the present invention, a manufacturing method of a semiconductor device which comprises preparing a substrate having a gate electrode film formed thereon and a gate insulation film formed between the substrate and the gate electrode film; and etching the gate electrode film formed on the gate insulation film of the substrate using an etching gas which contains a Si-containing gas and O₂, is provided.

### BRIEF DESCRIPTION OF THE DRAWINGS

FIG. 1A to FIG. 1C are views schematically showing a process of manufacturing an n-channel MOSFET and a p-channel MOSFET according to an embodiment.

FIG. 2A to FIG. 2C are views schematically showing the process of manufacturing the n-channel MOSFET and the p-channel MOSFET according to the embodiment.

FIG. 3A to FIG. 3C are views schematically showing the process of manufacturing the n-channel MOSFET and the p-channel MOSFET according to the embodiment.

FIG. 4 is a view schematically showing the process of manufacturing the n-channel MOSFET and the p-channel MOSFET according to the embodiment.

FIG. 5 is a schematic block diagram of an etching system used to etch a gate electrode according to the embodiment.

FIG. 6A is an electron micrograph showing a sectional shape of a gate electrode according to experimental example 1 and FIG. 6B is an electron micrograph showing a sectional shape of a gate electrode according to experimental example 2.

### DETAILED DESCRIPTION

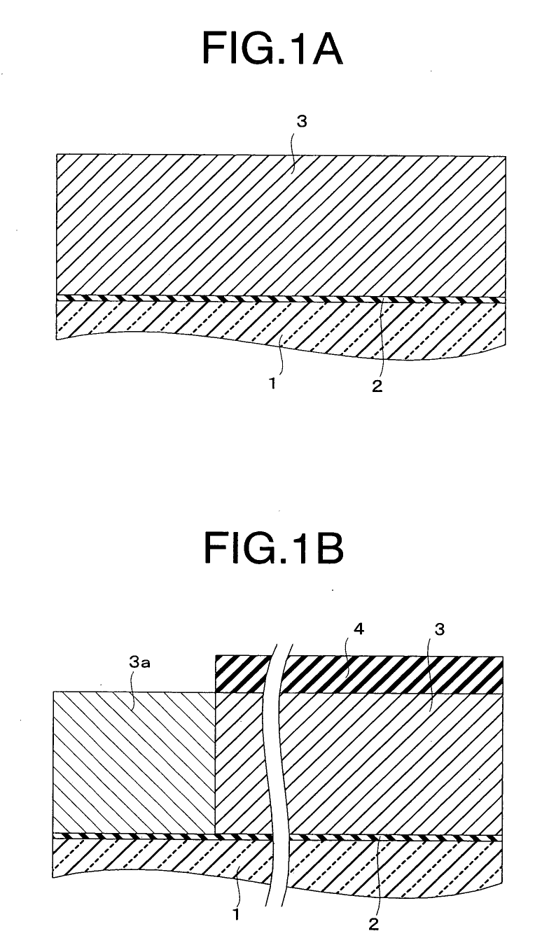

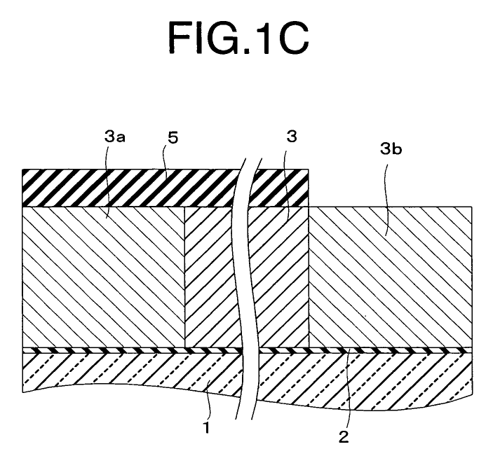

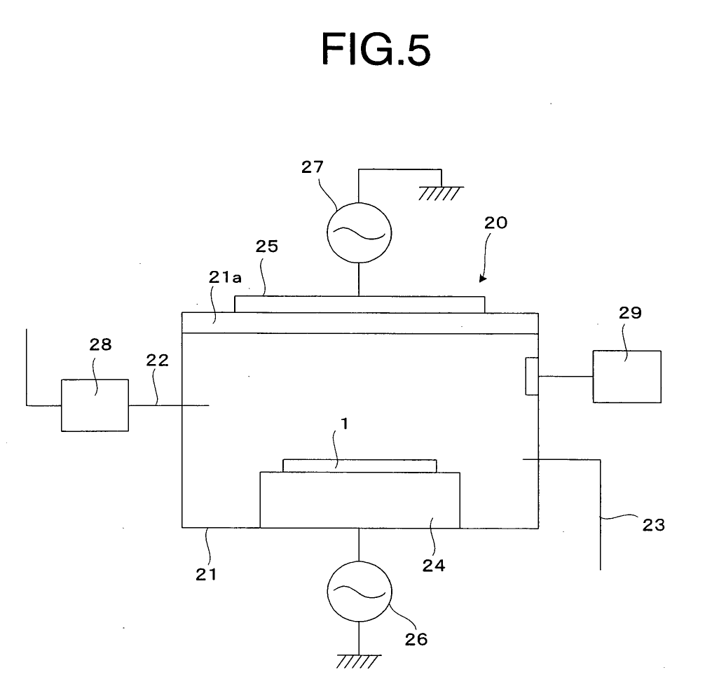

Hereinafter, an embodiment according to the present invention will be described with reference to the drawings. In the present embodiment, a process of manufacturing an n-channel MOSFET and a p-channel MOSFET on a semiconductor substrate will be described. FIG. 1 to FIG. 4 are views schematically showing a process of manufacturing the n-channel MOSFET and the p-channel MOSFET according to the present embodiment and FIG. 5 is a schematic block diagram of an etching system used to etch a gate electrode film according to the present embodiment.

First, a gate insulation film 2 is formed on a semiconductor substrate 1 composed, for example, of monocrystalline Si or the like by, for example, Chemical Vapor Deposition (CVD); and a gate electrode film 3 is formed on the gate insulation film 2 by, for example, CVD (FIG. 1A).

The gate insulation film 2 may be composed of at least any of Hf-based oxide, Zr-based oxide and Si-based oxide. As a Hf-based oxide, for example, at least, any of Hf silicate (Hf—Si—O), Hf aluminate (Hf—Al—O), hafnium oxide (HfO₂), and so forth can be cited. As a Zr-based oxide, for example, at least, any of Zr silicate (Zr—Si—O), Zr aluminate (Zr—Al—O), zirconium oxide (ZrO₂), and so forth can be cited. As a Si-based oxide, for example, at least, any of SiON and SiO₂ can be cited. In the present embodiment, an example in which the gate insulation film 2 is composed of Hf-based oxide and the gate electrode film 3 is composed of polysilicon or the like will be described.

Subsequently, a resist pattern 4 formed by, for example, a photo resist that has an opening in the region to form the n-channel MOSFET is formed on the gate electrode film 3 and phosphor (P) or arsenic (As) is introduced into the gate electrode film 3 using the resist pattern 4 as a mask to form an n-type gate electrode film 3a as a gate electrode film (FIG. 1B). After that, the photo resist pattern 4 is removed for example by ashing using O₂.

Further, a resist pattern 5 formed by, for example, a photo resist that has an opening in the region to form the p-channel MOSFET is formed on the n-type gate electrode film 3a and boron (B) is introduced into the gate electrode film using the resist pattern 5 as a mask to form a p-type gate electrode film 3b as a gate electrode film (FIG. 1C). After that, the photo resist pattern 5 is removed for example by ashing using O₂.

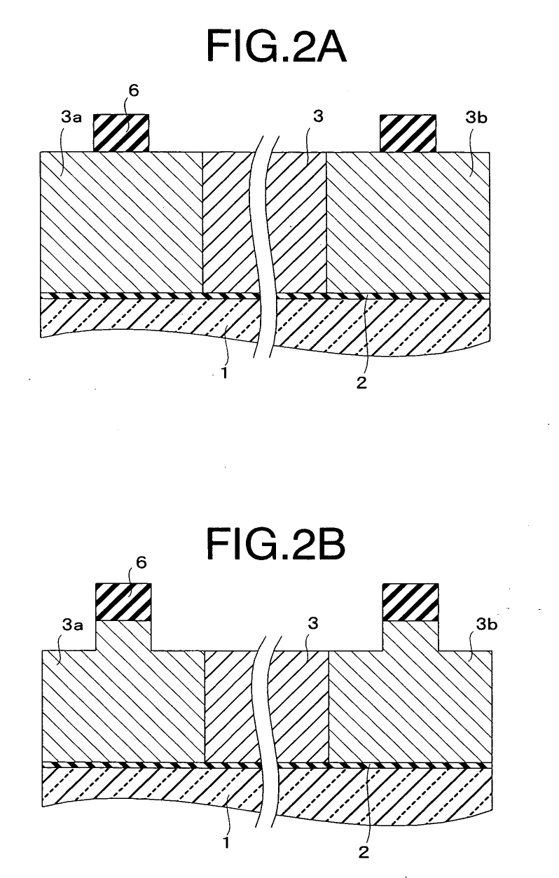

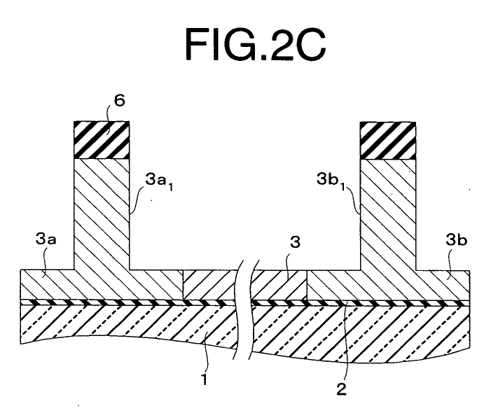

Subsequently, hard masks 6 having an opening in the region except the region to form the gate electrode of the n-channel MOSFET and the gate electrode of the p-channel MOSFET are formed on the n-type gate electrode film 3a and the like (FIG. 2A). The hard mask 6 is composed of, for example, SiO₂ or the like.

After the hard masks 6 are formed on the n-type gate electrode film 3a and the like, dry etching is performed to the n-type gate electrode film 3a, the p-type gate electrode film 3b and the like existing in the region except the region to form the gate electrode by way of Reactive Ion Etching (RIE) using the hard mask 6 as a mask with the use of an etching system 20 shown in FIG. 5.

The etching system 20 is an Inductively Coupled Plasma (ICP) apparatus. The etching system 20 is mainly composed of a chamber 21 having a dielectric plate 21a at the upper portion thereof, a gas introduction line 22 introducing later-described first to third etching gases into the chamber 21, an exhaust line 23 exhausting the chamber 21, a lower electrode 24 disposed in the chamber 21 and allowing the semiconductor substrate 1 to be placed thereon, an antenna 25 disposed on the dielectric plate 21a, a high-frequency power supply 26 supplying high-frequency electric power to the lower electrode 24, a high-frequency power supply 27 supplying high-frequency electric power to the antenna 25, a flowmeter 28 measuring flow rates of the first to third etching gases, and a pressure gage 29 measuring the pressure in the chamber 21.

In the state where the semiconductor substrate 1 having the hard mask 6 and the like formed thereon is placed on the lower electrode 24 of such an etching system 20, the high-frequency electric power is supplied from the high-frequency power supply 27 to the antenna 25 and the first etching gas and the like are supplied into the chamber 21 to form plasma, and at the same time, the high-frequency electric power is supplied from the high-frequency power supply 26 to the lower electrode 24 to perform etching to the n-type gate electrode film 3a and the like existing in the region except the region to form the gate electrode.

This etching is performed through many steps. Specifically, since a natural oxide film is sometimes formed on the surface of the n-type gate electrode film 3a and the like during the delivery into the chamber 21, first, etching is performed to the upper portions (upper layer portions) of the n-type gate electrode film 3a and the like existing in the region except the region to form the gate electrode so as to remove the natural oxide film (FIG. 2B). The first etching gas contains, at least, any of CF₄, SF₆, NF₃ and CHF₃, as an example.

After the upper portions of the n-type gate electrode film 3a and the like are etched, the middle portions (middle layer portions) of the n-type gate electrode film 3a and the like existing in the region except the region to form the gate electrode is etched using the HBr-based second etching gas under the condition where ion energy is relatively high (FIG. 2C). Here, this step is performed under the condition of relatively high ion energy where anisotropy element increases, so that a sidewall 3a₁ of the n-type gate electrode film 3a and a sidewall 3b₁ of the p-type gate electrode film 3b existing in the region to form the gate electrode are etched almost vertically.

The second etching gas contains, for example, Cl₂ and the like in addition to HBr. Note that since this step is stopped in the state where the gate insulation film 2 is not exposed, it is possible to use the gas of which etching selectivity of the n-type gate electrode film 3a and the like to the gate insulation film 2 is not so high as a second etching gas. Further, by monitoring the film thickness of the n-type gate electrode film 3a and the like in real time by a coherent endpoint detector, or by being based on the time experimentally obtained in advance, the etching can be stopped in the state in which the gate insulation film 2 is not exposed.

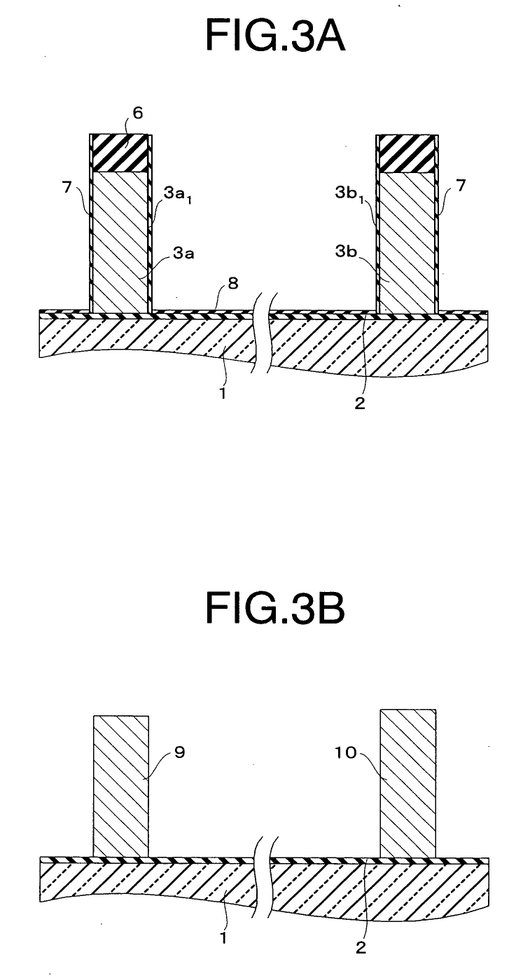

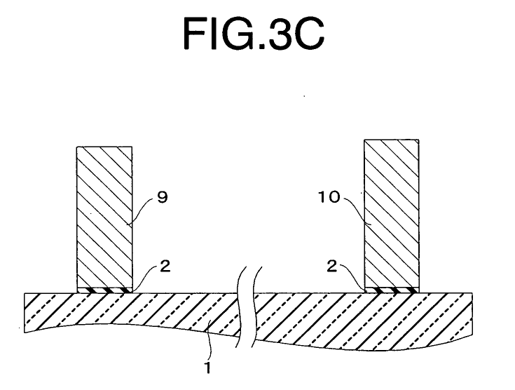

After the middle portions of the n-type gate electrode film 3a and the like are etched, the lower portions (lower layer portions) of the n-type gate electrode film 3a and the like existing in the region except the region to form the gate electrode is etched under the condition of relatively low ion energy using a HBr-based third etching gas containing, for example, SiF₄ as a Si-containing gas and O₂ to the extent that the surface of the gate insulation film 2 is exposed (FIG. 3A).

The third etching gas contains, for example, N₂ in addition to HBr, SiF₄ and O₂. Note that the base of the third etching gas may be other than HBr. Further, the Si-containing gas is not limited to SiF₄. Specifically, the Si-containing gas may be at least any of SiCl₄ and SiH₂Cl₂, as an example, in addition to SiF₄.

The contained ratio of the Si-containing gas in the third etching gas is preferably 0.5 vol % or more and 10 vol % or less of the whole third etching gas. The reason of this range, which is defined to be preferable, is when the ratio is below 0.5 vol %, a later-described protective film 7 is not formed effectively, in which the effect to protect the sidewall 3a₁ of the n-type gate electrode film 3a is weak; and when the ratio is over 10 vol %, F (fluorine) and Cl (chlorine) increase, in which the sidewall 3a₁ of the n-type gate electrode film 3a and the like are possibly etched. Further, the contained ratio of the O₂ in the third etching gas is preferably 0.5 vol % or more and 6 vol % or less of the whole third etching gas. This reason of this range, which is defined to be preferable, is when the ratio is below 0.5 vol %, it is difficult to obtain enough etching selectivity of the n-type gate electrode film 3a and the like as compared to the gate insulation film 2; and when the ratio is over 6 vol %, the etch rate with respect to the n-type gate electrode film 3a and the like falls to possibly lose the etch uniformity in the surface.

As a third etching gas as described above, such a gas that has an etching selectivity of, for example, 50 or more for the n-type gate electrode film 3a and the like to the gate insulation film 2 is preferably used.

When etching is performed using the third etching gas containing SiF₄, the etching proceeds while forming the protective film 7 on the sidewall 3a₁ of the n-type gate electrode film 3a and the like. The protective film 7 is mainly composed of SiO₂ being a reaction product of Si of SiF₄ and O₂, and SiON being a reaction product of Si of SiF₄ and N₂. Here, SiO₂ and SiON are difficult to be etched by HBr and the like. Hence, with the formation of the protective film 7, it is possible to prevent the n-type gate electrode film 3a and the like from the side etching in the step of exposing the gate insulation film 2 by way of etching the lower portions of the n-type gate electrode film 3a and the like.

Further, when the etching has proceeded to expose the gate insulation film 2, HfFₓ (x=1 to 4) being a reaction product of Hf contained in the gate insulation film 2 and F of SiF₄ is formed on the surface of the gate insulation film 2. Since the HfFₓ has a low vapor pressure, it is deposited on the surface of the gate insulation film 2 to form a protective film 8. With this, even when the gate insulation film 2 is exposed, the gate insulation film 2 is difficult to be etched, so that the gate insulation film 2 is prevented from being broken by overetching. Note that the protective film 8 is mainly composed of HfFₓ, however, the other compound is mixed therein as well.

When SiCl₄ or SiH₂Cl₂ is used instead of using SiF₄ as a Si-containing gas, HfClₓ (x=1 to 4) is formed in return for HfFₓ, however, the same effect as of HfFₓ can be obtained even with HfClₓ. However, since the vapor pressure of HfFₓ is lower than that of HfClₓ, it is preferable to use SiF₄ as a Si-containing gas.

When the gate insulation film 2 is composed of Zr-based oxide, ZrFₓ (x=1 to 4) or ZrClₓ (x=1 to 4), which has a low vapor pressure, is formed as in Hf-based oxide, in which the protective film 8 is formed as in Hf-based oxide, so that the same effect can be obtained.

When the gate insulation film 2 is composed of Si-based oxide, the protective film 8 is not formed since a reaction product with Si of Si-based oxide has a relatively high vapor pressure, whereas SiCl₄ and SiH₂Cl₂ show low reactivity with respect to Si of Si-based oxide, therefore, at least, SiCl₄ or SiH₂Cl₂ is preferably used.

After the lower portions of the n-type gate electrode film 3a and the like are etched, etch residues of the n-type gate electrode film 3a and the like is removed completely; after that, wet etching is performed using for example dilute hydrofluoric acid (DHF) or the like to remove the protective film 7 formed on the sidewall 3a₁ of the n-type gate electrode film 3a and the like and the protective film 8 formed on the surface of the gate insulation film 2. Also, the hard masks 6 are removed (FIG. 3B). With this, an n-type gate electrode 9 and a p-type gate electrode 10 are formed in the regions to form gate electrodes.

After the n-type gate electrode 9 and the p-type gate electrode 10 are formed, the other gate insulation film 2 is removed by wet etching so as to leave the gate insulation film 2 just under the n-type gate electrode 9 and the p-type gate electrode 10 (FIG. 3C).

After that, a resist pattern (not shown) having openings for the regions to form a source and a drain of the n-channel MOSFET is formed to form n-type source/drain regions 11 in the semiconductor substrate 1 on both sides of the n-type gate electrode 9 (the surface layer of the semiconductor substrate 1, in the region in the vicinity of the n-type gate electrode 9 not formed) by introducing phosphor or arsenic into the region to form the source and drain of then-channel MOSFET. After that, the photo resist pattern is removed for example by ashing using O₂

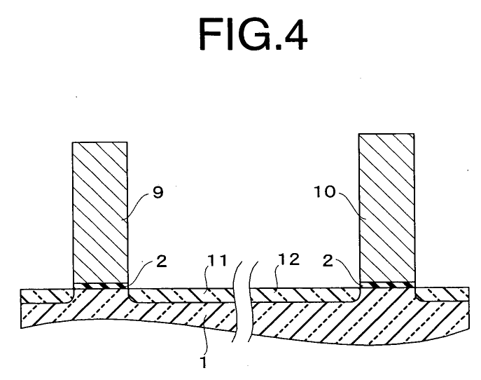

Further, a resist pattern (not shown) having openings for the regions to form a source and a drain of the p-channel MOSFET is formed to form p-type source/drain regions 12 in the semiconductor substrate 1 on both sides of the p-type gate electrode 10 (the surface layer of the semiconductor substrate 1, in the region in the vicinity of the p-type gate electrode 10 not formed) by introducing boron into the region to form the source and drain of the p-channel MOSFET. After that, the photo resist pattern is removed for example by ashing using O₂ (FIG. 4).

In the present embodiment, in the step to expose the gate insulation film 2 by etching the lower portions (lower layer portions) of the n-type gate electrode film 3a and the like, the third etching gas containing SiF₄ and O₂ is used, therefore the protective film 7 can be formed on the sidewall 3a₁ of the n-type gate electrode film 3a and the like. Accordingly, as described above, even when the lower portion of the n-type gate electrode film 3a to form the n-channel MOSFET and the lower portion of the p-type gate electrode film 3b to form the p-channel MOSFET, which are formed on the same semiconductor substrate, are etched at once, the side etching of the n-type gate electrode film 3a can be prevented by the protective film 7.

Note that, when the effect of the protective film 7 is excessively large, there is a possibility that the portion that should be etched is not etched in the step to expose the gate insulation film 2 by etching the lower portions of the n-type gate electrode film 3a and the like, to cause the sidewall 3a₁ of the n-type gate electrode film 3a and the like have a shape of draggling its tail. On the other hand, in the present embodiment, since the third etching gas is made to contain N₂, it is easily possible to control the shape of the sidewall 3a₁ of the n-type gate electrode film 3a and the like by adjusting the flow rate of N₂. Here, the contained ratio of the N₂ in the third etching gas is preferably 10 vol % or less of the whole third etching gas. This is because when the ratio exceeds 10 vol %, the etch rate of the n-type gate electrode film 3a and the like falls to possibly lose the etch uniformity in the surface.

Further, in the present embodiment, in the step to expose the gate insulation film 2 by etching the lower portions of the n-type gate electrode film 3a and the like, it is possible to form the protective film 8 on the surface of the gate insulation film 2 in that the third etching gas containing SiF₄ and O₂ is used and, at the same time, the gate insulation film 2 is composed of Hf-based oxide as described above, so that the gate insulation film 2 can be prevented from being broken by overetching.

### EXPERIMENTAL EXAMPLES

Hereinafter, the description will be given of experimental examples. In the present experimental examples, the shape of the gate electrode in the case where the lower portion of the gate electrode film is etched using an etching gas containing SiF₄ and that in the case where the lower portion of the gate electrode film is etched using an etching gas not containing SiF₄ are observed respectively by an electron microscope.

Specifically, a polysilicon film (gate electrode film) of a mat film (a film formed to have no space) is formed on an HfO₂ film (gate insulation film) and further a hard mask having an opening at a predetermined position is formed on the polysilicon film, and etching is performed to the polysilicon film using the hard mask as a mask to thereby form a gate electrode of polysilicon.

In an experimental example 1, when etching the lower portion of the polysilicon film in which the HfO₂ film is exposed, the etching gas containing SiF₄ is used. The etching gas, which is composed of HBr, O₂, N₂ and SiF₄, is supplied so that the flow rates come to HBr/O₂/N₂/SiF₄=150 sccm/10 sccm/2 sccm/3 sccm, respectively. Further, in the etching, the etching system shown in the above-descried embodiment is used, in which the pressure in the chamber is kept at 8 mToor, a high-frequency electric power of 600 W is supplied to the antenna, and a high-frequency electric power of 25 W is supplied to the lower electrode.

Meanwhile, in an experimental example 2, when etching the lower portion of the polysilicon film in which the HfO₂ film is exposed, the etching gas not containing SiF₄ is used. The etching gas is composed of HBr, O₂ and N₂, and is supplied so that the flow rates come to HBr/O₂/N₂=150 sccm/2 sccm/2 sccm, respectively. Further, in the etching, the etching system shown in the above-descried embodiment is used, in which the pressure in the chamber is kept at 8 mToor, a high-frequency electric power of 600 W is supplied to the antenna, and a high-frequency electric power of 25W is supplied to the lower electrode.

The gate electrodes formed under such conditions are observed respectively by the electron microscope.

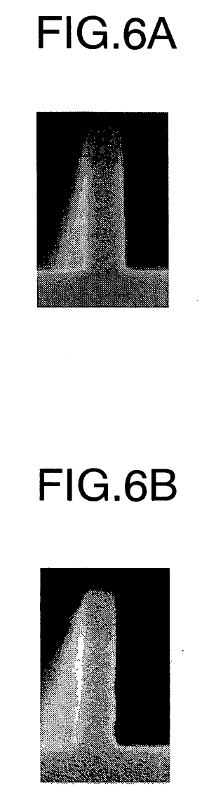

Hereinafter, the description will be given of the experimental results. FIG. 6A is an electron micrograph showing a sectional shape of the gate electrode according to the experimental example 1 and FIG. 6B is an electron micrograph showing a sectional shape of the gate electrode according to the experimental example 2.

In the experimental example 2, the lower portion of the gate electrode was recessed as shown in FIG. 6B due to the side etching occurred. On the other hand, in the experimental example 1, a protective film was formed on the sidewall of the gate electrode film, preventing side etching from occurring, so that the lower portion of the gate electrode was not recessed virtually as shown in FIG. 6A.

Based on this result, it was confirmed that the side etching can be prevented when the etching gas containing SiF₄ is used in the step of etching the lower portion of the gate electrode film.

It is to be understood that the present invention is not limited to the description of the above-described embodiment, and configurations, materials, arrangements of respective members, and so forth are appropriately changeable within the scope not departing from the gist of the present invention.

According to the manufacturing method of the semiconductor device of one aspect of the present invention, the side etching of the gate electrode film in the step of exposing the gate insulation film can be prevented.

What is claimed is:

1. A manufacturing method of a semiconductor device, comprising:
preparing a substrate having a gate electrode film formed thereon and a gate insulation film formed between the substrate and the gate electrode film; and
etching the gate electrode film formed on the gate insulation film of the substrate using an etching gas which contains a Si-containing gas and O₂.

2. The manufacturing method of the semiconductor device as set forth in claim 1,
wherein said etching is performed to expose the gate insulation film.

3. The manufacturing method of the semiconductor device as set forth in claim 1,
wherein the etching gas further contains HBr.

4. The manufacturing method of the semiconductor device as set forth in claim 1,
wherein the etching gas further contains N₂.

5. The manufacturing method of the semiconductor device as set forth in claim 1,
wherein the gate insulation film contains at least any of Hf and Zr.

6. The manufacturing method of the semiconductor device as set forth in claim 1,
wherein the gate insulation film is composed of at least any of Hf-based oxide, Zr-based oxide and Si-based oxide.

7. The manufacturing method of the semiconductor device as set forth in claim 1,
wherein the gate insulation film is composed of at least any of Hf silicate (Hf—Si—O), Hf aluminate (Hf—Al—O), and hafnium oxide (HfO₂).

8. The manufacturing method of the semiconductor device as set forth in claim 1,
wherein the gate electrode film is composed of polysilicon.

9. The manufacturing method of the semiconductor device as set forth in claim 8,
wherein the etching the gate electrode film includes etching a first conductivity type of gate electrode film and a second conductivity type of gate electrode film at once, the second conductivity type of gate electrode film having reverse conductivity of the first conductivity type of gate electrode film.

10. The manufacturing method of the semiconductor device as set forth in claim 1,
wherein the Si-containing gas is at least any of SiF₄, SiCl₄, and SiH₂Cl₂.

11. The manufacturing method of the semiconductor device as set forth in claim 7,
wherein the Si-containing gas is SiF₄.

12. The manufacturing method of the semiconductor device as set forth in claim 1,
wherein the etching gas contains the Si-containing gas at a ratio of 0.5 vol % or more and 10 vol % or less.

13. The manufacturing method of the semiconductor device as set forth in claim 1,
wherein the etching gas contains O₂ at a ratio of 0.5 vol % or more and 6 vol % or less.

14. The manufacturing method of the semiconductor device as set forth in claim 4,
wherein the etching gas contains N₂ at a ratio of 10 vol % or less.

15. The manufacturing method of the semiconductor device as set forth in claim 1,
wherein the etching gas has an etching selectivity of 50 or more for the gate electrode film as compared to the gate insulation film.

16. The manufacturing method of the semiconductor device as set forth in claim 1, further comprising:
etching the gate electrode film of the substrate using a HBr-based etching gas containing Cl₂, before said etching the gate electrode film using the etching gas which contains the Si-containing gas and O₂.

17. The manufacturing method of the semiconductor device as set forth in claim 16,
wherein the etching using the HBr-based etching gas containing Cl₂ is performed under higher ion energy condition than the etching using the etching gas which contains the Si-containing gas and O₂.

18. The manufacturing method of the semiconductor device as set forth in claim 16,
wherein said etching using the HBr-based etching gas containing Cl₂ is stopped in the state of not exposing the gate insulation film.

19. The manufacturing method of the semiconductor device as set forth in claim 1, further comprising:
etching the gate electrode film of the substrate using an etching gas containing at least any of CF₄, SF₆, NF₃ and CHF₃, before said etching the gate electrode film using the etching gas which contains the Si-containing gas and O₂.

20. The manufacturing method of the semiconductor device as set forth in claim 1, further comprising:
etching the gate electrode film of the substrate using an etching gas containing at least any of CF₄, SF₆, NF₃ and CHF₃; and subsequently,
etching the gate electrode film of the substrate using a HBr-based etching gas containing Cl₂, before said etching the gate electrode film using the etching gas which contains the Si-containing gas and O₂.
